(19) United States
(12) Patent Application Publication
(10) Pub. No.: US 2015/0076695 A1
(43) Pub. Date: Mar. 19, 2015

(54) SELECTIVE PASSIVATION OF VIAS

(71) Applicant: International Business Machines Corporation, Armonk, NY (US)

(72) Inventors: Tien-Jen Cheng, Bedford, NY (US); Lawrence A. Clevenger, LaGrangeville, NY (US); Terence L. Kane, Wappingers Falls, NY (US); Carl J. Radens, LaGrangeville, NY (US); Andrew H. Simon, Fishkill, NY (US); Yun-Yu Wang, Poughquag, NY (US); Yiheng Xu, Hopewell Junction, NY (US); John Zhang, Albany, NY (US)

(73) Assignees: STMICROELECTRONICS, INC., Coppell, TX (US); International Business Machines Corporation, Armonk, NY (US)

(21) Appl. No.: 14/027,556

(22) Filed: Sep. 16, 2013

(51) Int. Cl. H01L 23/532; H01L 21/768

(52) U.S. Cl. CPC H01L 23/53238; H01L 21/76849
USPC 257/751; 438/637

(57) ABSTRACT

A method of forming an integrated circuit structure includes forming a cap layer above a first ILD layer of a first metal level, the first ILD layer includes a recess filled with a first conductive material to form a first interconnect structure. Next, a second ILD layer is formed above the cap layer and a via is formed within the second ILD layer as a second interconnect structure of a second metal level. The via is aligned with the first interconnect structure. Subsequently, a portion of the cap layer is removed to extend the via to expose a top portion of the first conductive material then a passivation cap is selectively formed at a bottom portion of the via in the second ILD layer and the passivation cap contacting the top portion of the first conductive material. The passivation cap includes a metal alloy to form an interface between the bottom portion of the via and the first conductive material.

### BACKGROUND

The present invention generally relates to integrated circuits and more particularly to interconnect structures including passivated vias, and a method for making the same.

Typical components of an integrated circuit include transistors, capacitors, and the like. In semiconductor chip fabrication, these components are coupled by interconnect structures to conduct current through the different circuit layers. Such interconnect structures typically take the shape of wires, trenches, or vias formed in dielectric layers above the microelectronic devices and may typically be formed by depositing a dielectric layer, etching a recess in the dielectric layer and filling the recess with a metal. Currently, interconnect structures are usually made of copper and may be formed using a single-damascene or dual-damascene fabrication process. In the single-damascene process, interconnect structures (vias and trenches) are manufactured independently, while in the dual-damascene process are manufactured at the same time.

As integrated circuits continue to shrink, vias may exhibit a higher aspect ratio. Typical processes used to fill vias with reduced width frequently form voids in the via which adversely affect the conductivity and reliability of the interconnect structure. Usually, the vias may be lined with a barrier layer. The presence of such barrier layers between the dielectric layer and the metal layer has significantly decreased electromigration problems in integrated circuits. Electromigration may be defined as the material transport induced by the electron flow during operation under current. The interface between the interconnect structure and the surrounding dielectric may present the primary path for the material transport in metal lines.

Despite the implementation of barrier layers voids continue to form at a weak interface between the via bottom and the copper layer underneath causing failure of reliability tests due to electromigration yield loss. Early voiding detrimentally affects vias performance representing a critical electromigration resistance (yield) concern in back-end-of-the-line (BEOL) technologies.

### SUMMARY

According to one embodiment of the present invention, a method of forming an integrated circuit structure, includes: forming a cap layer above a first ILD layer of a first metal level, the first ILD layer includes a recess filled with a first conductive material to form a first interconnect structure, forming a second ILD layer above the cap layer, forming a via within the second ILD layer as a second interconnect structure of a second metal level, the via being aligned with the first interconnect structure, removing a portion of the cap layer to extend the via to expose a top portion of the first conductive material and selectively forming a passivation cap at a bottom portion of the via in the second ILD layer and the passivation cap contacting the top portion of the first conductive material, the passivation cap includes a metal alloy to form an interface between the bottom portion of the via and the first conductive material.

According to another embodiment of the present invention, a method of forming an integrated circuit structure, includes: forming a cap layer above a first ILD layer of a first metal level, the first ILD layer including a recess filled with a first conductive material to form a first interconnect structure, forming a second ILD layer above the cap layer, forming a dual damascene opening having a via and a trench within the second ILD layer, the via being aligned with the first interconnect structure, removing a portion of the cap layer to extend the via to expose a top portion of the first conductive material, selectively forming a passivation cap at a bottom portion of the via in the second ILD layer and the passivation cap contacting the top portion of the first conductive material, the passivation cap including a metal alloy to form an interface between the bottom portion of the via and the first conductive material, forming a barrier liner on a perimeter formed by an exposed surface of the via, an exposed surface of the trench, an uppermost part of the second ILD layer and an exposed surface of the passivation cap and filling the via and the trench with a second conductive material.

According to another embodiment of the present invention, an integrated circuit structure includes: a first ILD layer having a recess filled with a first conductive material being part of a first interconnect structure of a first metal level, a second ILD layer having a recess filled with a second conductive material being part of a second interconnect structure of a second metal level, the second interconnect structure includes a via extending to a top portion of the first conductive material, a cap layer positioned between the first ILD layer and the second ILD layer located essentially in an area between two vias and a passivation cap positioned at a bottom portion of the via and at an exposed top portion of the first conductive material, the passivation cap forms an interface between the via bottom and the first conductive material.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIG. 1 is a cross-sectional view of a partially formed integrated circuit structure having a first metal level including trenches in a first ILD layer, according to an embodiment of the present disclosure;

FIG. 2 is a cross-sectional view depicting the formation of a second ILD layer over the structure first metal level, according to an embodiment of the present disclosure;

FIG. 3 is a cross-sectional view depicting the formation of vias and trenches in the second ILD layer, according to an embodiment of the present disclosure;

FIG. 4 is a cross-sectional view depicting the formation of a passivation cap located between a bottom portion of the vias and an exposed portion of a first conductive material located in the structure first metal level, according to an embodiment of the present disclosure;

FIG. 5 is a cross-sectional view depicting the formation of a barrier liner on a perimeter of the integrated circuit structure, according to an embodiment of the present disclosure;

FIG. 6 is a cross-sectional view depicting the formation of a second conductive material in the vias and trenches above the barrier liner, according to an embodiment of the present disclosure; and

FIG. 7 is a cross-sectional view depicting a final integrated circuit structure after a planarization process is conducted, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

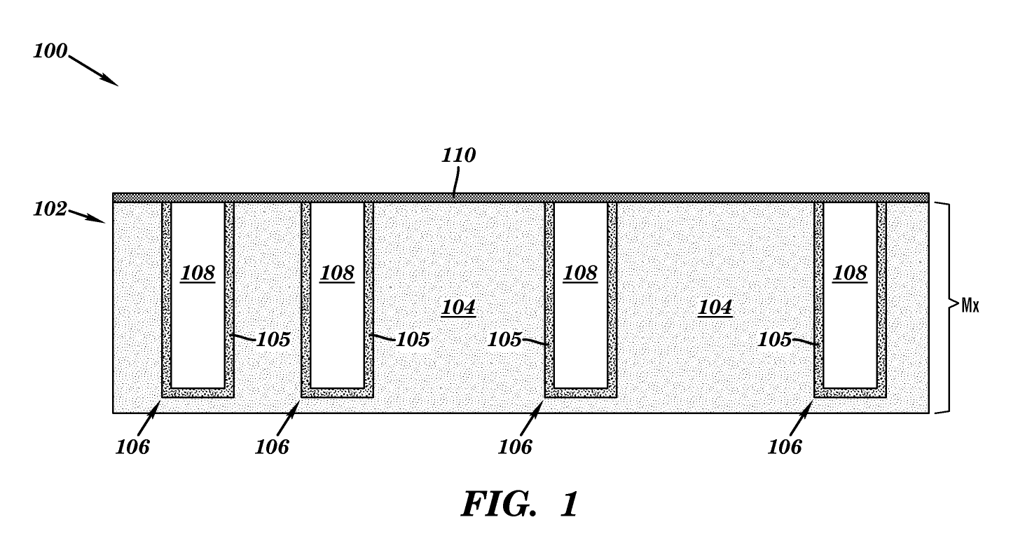

A method of manufacturing an integrated circuit structure is described in detail below by referring to the accompanying drawings in FIGS. 1-7, in accordance with some illustrative embodiments of the present invention.

Referring to FIG. 1, a cross-sectional view of a partially formed integrated circuit structure 100 is shown according to an embodiment of the present disclosure. At this step of the fabrication process, the structure 100 may include a wiring layer. If such wiring layer is the lowest wiring level then it may be referred to as a first metal level or M_{X} level 102. The first metal level 102 may include an insulating material, such as, for example a first interlayer dielectric (ILD) layer 104. The first ILD layer 104 may include any suitable dielectric material, for example, silicon oxide, silicon nitride, hydrogenated silicon carbon oxide, silicon based low-k dielectrics, or porous dielectrics. Known suitable deposition techniques, such as, for example, chemical vapor deposition (CVD), plasma-enhanced chemical vapor deposition (PECVD), spin on deposition, or physical vapor deposition (PVD) may be used to form the first ILD layer 104. The first ILD layer 104 may have a thickness ranging from about 100 nm to about 500 nm and ranges there between, although a thickness less than 100 nm and greater than 500 nm may be acceptable.

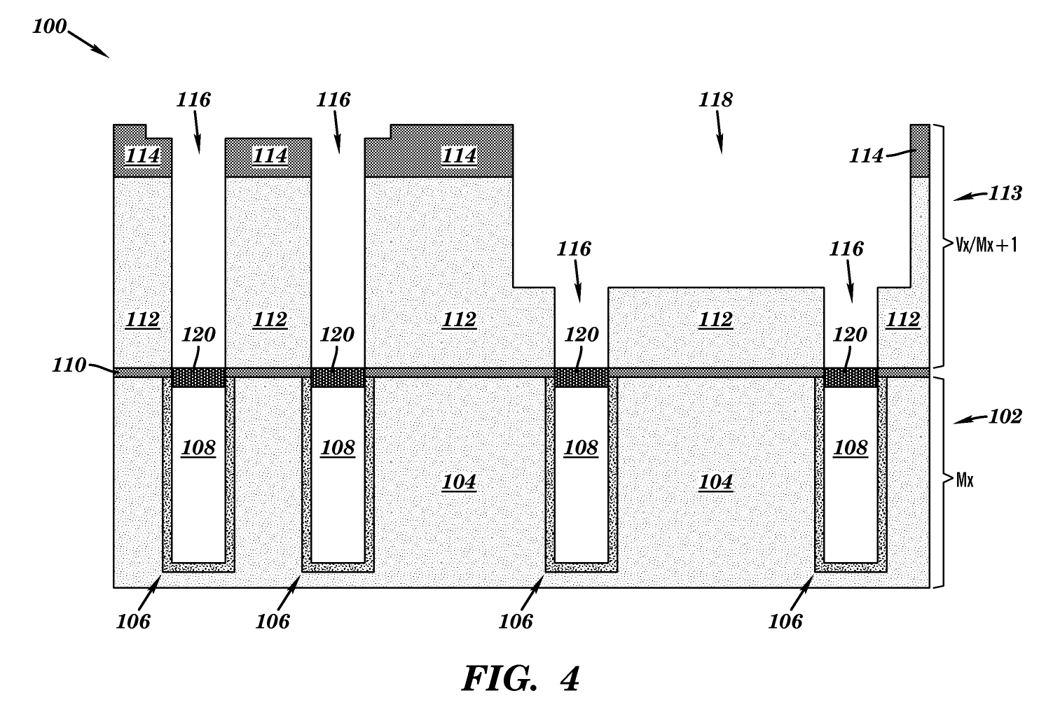

With continued reference to FIG. 1, the first metal level 102 may further include a first interconnect structure 106, the first interconnect structure may include a via or a trench patterned in the first ILD layer 104. The first interconnect structure 106 may be formed in the first ILD layer 104 using any method known in the art, for example, the first interconnect structure 106 may be formed by anisotropic etch of the first ILD layer 104 and then filled with a conductive material 108. Typically the conductive material 108 may be copper (Cu), however other metals such as aluminum (Al), gold (Au), silver (Ag) and tungsten (W) may also be considered. The conductive material 108 may be formed using a filling technique such as electroplating, electroless plating, CVD, PVD or a combination of methods. The conductive material 108 may further include a dopant, such as, for example, manganese (Mn), magnesium (Mg), copper (Cu), aluminum (Al), or other known dopants. In some embodiments, various barriers or liners, such as liner 105 may be formed in the first metal level 102. In one embodiment, a liner may include, for example, a tantalum nitride (TaN) layer, followed by a tantalum (Ta) layer. Other barrier liners may include cobalt (Co) or ruthenium (Ru), either alone or in combination with any other suitable liner. Alternatively, the first metal level 102 may include the various liners and barriers detailed below in conjunction with FIGS. 4-7.

The first metal level 102, may be referred to as a damascene structure and may be preferred for copper wiring and interconnects since it may structurally support the copper and can be fabricated with good precision because trenches may be formed more accurately than copper may be otherwise patterned.

Next, a cap layer 110 may be formed above the first metal level 102. The cap layer 110 may be deposited above the first metal level 102 by any deposition method known in the art such as CVD, plasma-enhanced chemical vapor deposition (PECVD), high-density CVD (HDCVD), or PVD. The cap layer 110 may have a thickness ranging from about 15 nm to about 30 nm and ranges there between, although a thickness less than 15 nm and greater than 30 nm may be acceptable.

The cap layer 110 may be provided in cases where the conductive material 108 includes copper (Cu). The cap layer 110 may include an insulator of silicon nitride, silicon carbide or the like which may function as both a barrier, particularly when a low-k material that may be subject to diffusion of moisture is used as the ILD layer, and an etch stop for a subsequent via level. In an embodiment of the present disclosure, the cap layer 110 may include a dielectric material such as nitrogen-doped silicon carbide (NBLoK).

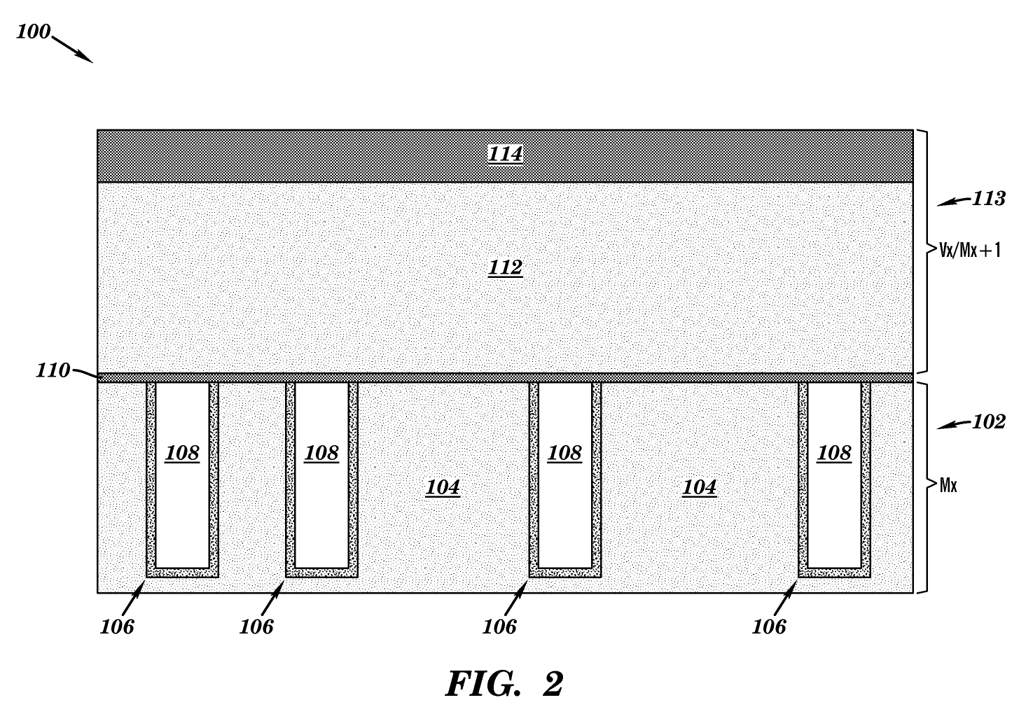

Referring now to FIG. 2, a second ILD layer 112 may be deposited above the cap layer 110. The second ILD layer 112 may be formed by any suitable deposition process such as: CVD, PECVD, HDCVD, PVD, plating, sputtering, evaporation, and chemical solution deposition of a dielectric material. The second ILD layer 112 may include: silicon oxide, silicon nitride, silicon oxynitride, carbon-doped silicon oxide or any other suitable dielectric material. The thickness of the second ILD layer 112 may range from about 100 nm to about 500 nm and ranges there between, although a thickness less than 100 nm and greater than 500 nm may be acceptable.

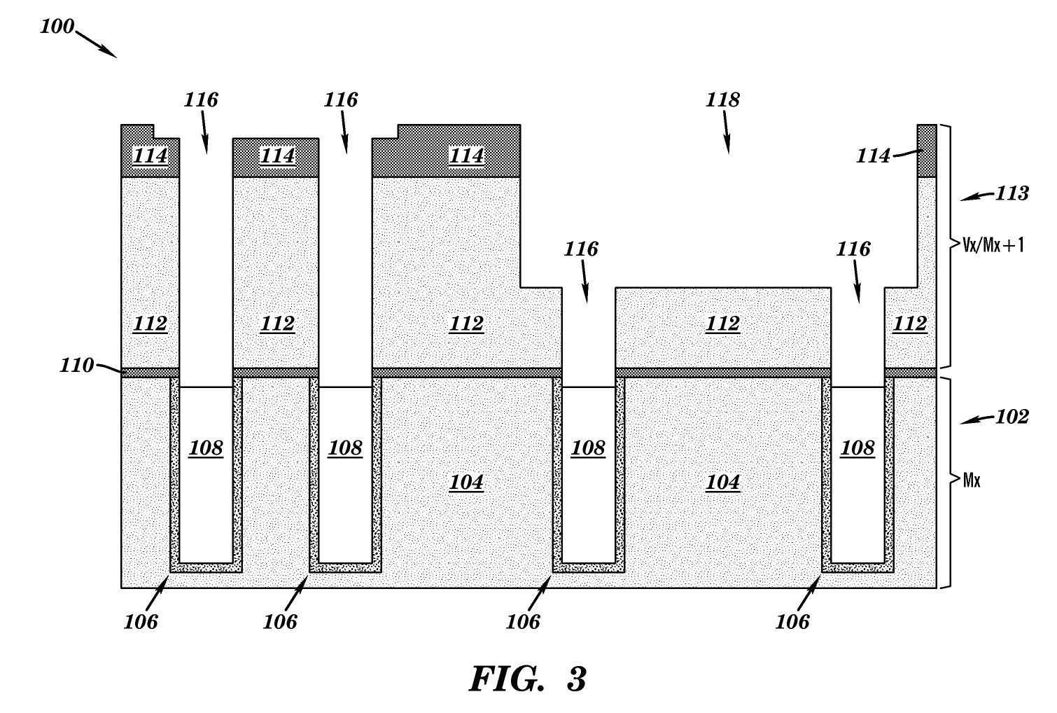

After deposition of the second ILD layer 112, a hardmask layer 114 may be deposited above the second ILD layer 112. The hard mask layer 114 may be formed by any deposition method known in the art. In one embodiment, the hard mask layer 114 may be formed by CVD of any known semiconductor material including, but not limited to: teos oxide, silicon nitride, silicon oxy-nitride and silicon carbide. A pattern may be lithographically formed in the hardmask layer 114 and then used to form vias and trenches in the second ILD layer 112 (as shown below in FIG. 3). The hardmask layer 114 may include one or more layers of the aforementioned materials.

FIG. 3 is a demonstrative illustration of the structure during an intermediate step of patterning the second ILD layer 112 and hard mask layer 114 to form second interconnect structures 116 (vias) and 118 (trenches). The second ILD layer 112 may be formed and patterned as both a barrier to copper out-diffusion and, particularly, to form the second interconnect structures, represented by vias 116 and trenches 118, in accordance with a particular chip design. At this step of the manufacturing process, the cap layer 110 may act as an etch stop. The cap layer 110 may then be opened using the patterned second ILD layer 112 as a mask by means of a method well-known in the art.

The second ILD layer 112 may act as a wiring layer and may be connected to the first metal level 102 underneath by a via 116 and as a result, if placed on top of the first metal level 102, the second ILD layer 112 may be identified as a second metal level 113 or V_{X}/M_{X+1} level, since it may be the first level with vias and the second level with metal interconnects. Vias and trenches of the second metal level 113 may represent a dual-damascene opening since two different patterning processes may be employed in forming the different depths of the wiring trenches and vias. However, other structures may be employed to which the invention may be equally applicable.

Vias 116 and trenches 118 may be formed in the second ILD layer 112 by lithographic methods and an anisotropic etch. For example, the hardmask layer 114 may be formed over a blanket film of the second ILD layer 112 without any pattern. The hardmask layer 114 may be lithographically patterned, and the pattern in the hardmask layer 114 may be transferred into the blanket film of the second ILD layer 112 by vertically recessing exposed portions forming the vias 116 and the trenches 118. An anisotropic etch such as a reactive ion etch may be used to recess the exposed surfaces. The hardmask layer 114 may be subsequently removed selective to the second ILD layer 112. The lithographic patterning may be employed repeatedly to form the vias 116 and the trenches 118 according to a determined chip design.

Formation of the via 116 may occur before forming the trench 118. Sidewalls of vias 116 and trenches 118 may be substantially vertical, however depending on the material of the second ILD layer 112 and the etch chemistry used to etch the vias and trenches, the sidewalls of the vias 116 and trenches 118 may have an inner deviation angle that may range from about 1 degree to about 10 degrees.

Recesses forming the vias 116 may extend until a top portion of a conductive material 108 is exposed. Exposing the conductive material 108 located in the first metal level 102 may include removal of a portion of the cap layer 110 located on top of the first conductive material 108. The first conductive material 108 may fill the first interconnect structure 106 located in the first metal level 102.

In dual-damascene schemes, the depth of the trenches 118 may vary from about 40% to about 80% of the thickness of the second ILD layer 112. In an embodiment of the present disclosure, the depth of the trenches 118 may vary from about 50% to about 70%, of the thickness of the second ILD layer 112. A structure having a single damascene scheme, may include trenches having the same depth as the thickness of the second ILD layer 112 or vias having the same depth as the thickness of the second ILD layer 112.

Referring now to FIG. 4, a passivation cap 120 may be formed between a top of the exposed portion of the first conductive material 108 and a bottom of the via 116. The passivation cap 120 may be selectively formed in areas where the first conductive material 108 is exposed at the bottom of the vias 116. Although the passivation cap 120 may be present in sidewalls of the vias 116, the amount positioned within the bottom of the vias may be substantially larger then the amount positioned in the sidewalls of the vias 116.

The passivation cap 120 may be made of a metal alloy having a thickness of approximately 3 nm to approximately 7 nm and ranges there between, although a thickness less than 3 nm and greater than 7 nm may be acceptable. In one embodiment, the passivation cap 120 may have a thickness of approximately 5 nm. The thickness of the passivation cap 120 may be adjusted, if necessary, during a subsequent reactive pre-clean (RPC) process.

In one embodiment of the present disclosure, the metal alloy forming the passivation cap 120 may include a copper-manganese (CuMn) alloy grown by a selective CVD process at the bottom of the via 116. The atomic percentage of manganese (Mn) in the copper-manganese alloy may range from about 0.1% to about 5%, and preferably from about 0.5% to about 2%. Because of the manganese in the copper-manganese alloy, the passivation cap 120 may provide strong adhesion to copper-containing materials, such as the first conductive material 108 underneath and other copper-containing materials which may be subsequently formed on top of the passivation cap 120.

In another embodiment of the present disclosure, the metal alloy forming the passivation cap 120 may include a cobalt-tungsten-phosphide (CoWP) alloy which can provide a better interface between the first conductive material 108 underneath and other copper-containing materials which may be subsequently formed on top of the passivation cap 120. In this embodiment, the passivation cap 120 may be formed by electroless plating of a cobalt-tungsten-phosphide alloy.

An advantage of an embodiment of the present invention may be that selectively passivating the via bottom by forming the passivation cap 120 may not increase the structure resistance-capacitance (RC) hence improving circuit performance.

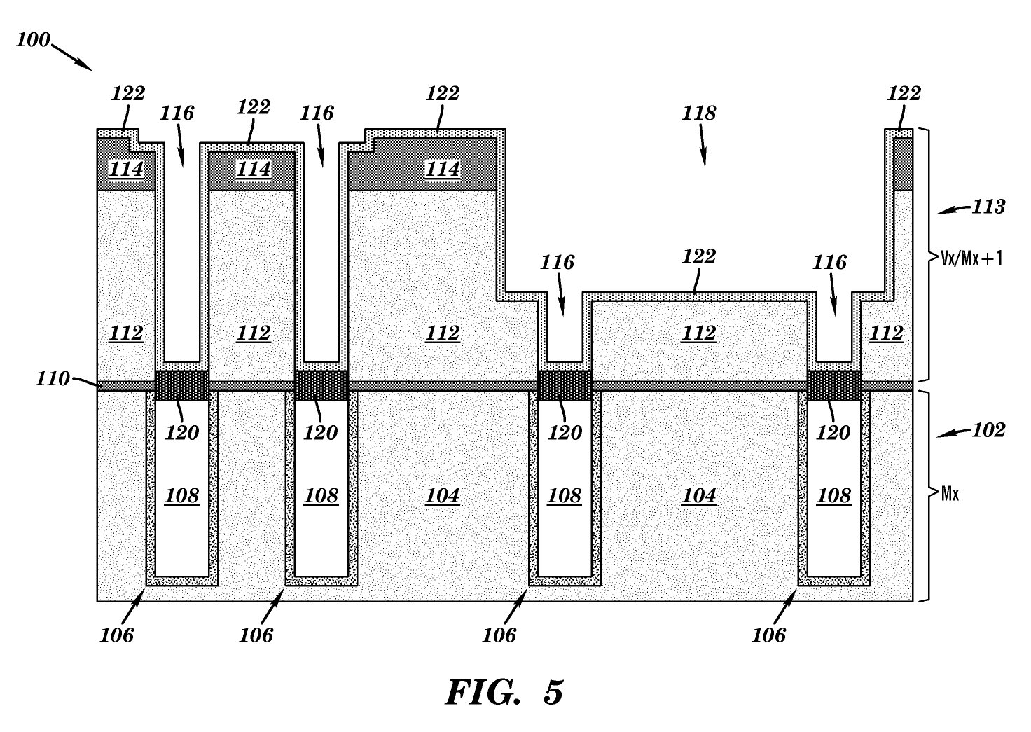

Referring now to FIG. 5, a barrier liner 122 may be directly deposited on a perimeter formed by all the exposed surfaces of the vias 116, the trenches 118, and uppermost surfaces of the passivation cap 120, the second ILD layer 112 and the hard mask layer 114.

The barrier liner 122 may be composed of titanium (Ti), tantalum (Ta), tungsten (W), titanium nitride (TiN), tantalum nitride (TaN), tungsten nitride (WN), a combination thereof, or an alloy thereof. The thickness of the barrier liner 122 may range from about 2 nm to about 10 nm and ranges there between, although a thickness less than 2 nm and greater than 10 nm may be acceptable. In an embodiment of the present disclosure, the barrier liner 122 may have a thickness of approximately 5 nm. The barrier liner 122 may adhere to the second ILD layer 112 and the passivation cap 120 hindering the diffusion of conductive materials such as copper or impurities such as oxygen across the barrier liner 122. The barrier liner 122 may be formed by PVD, CVD, electroless plating, evaporation, or any other suitable deposition method.

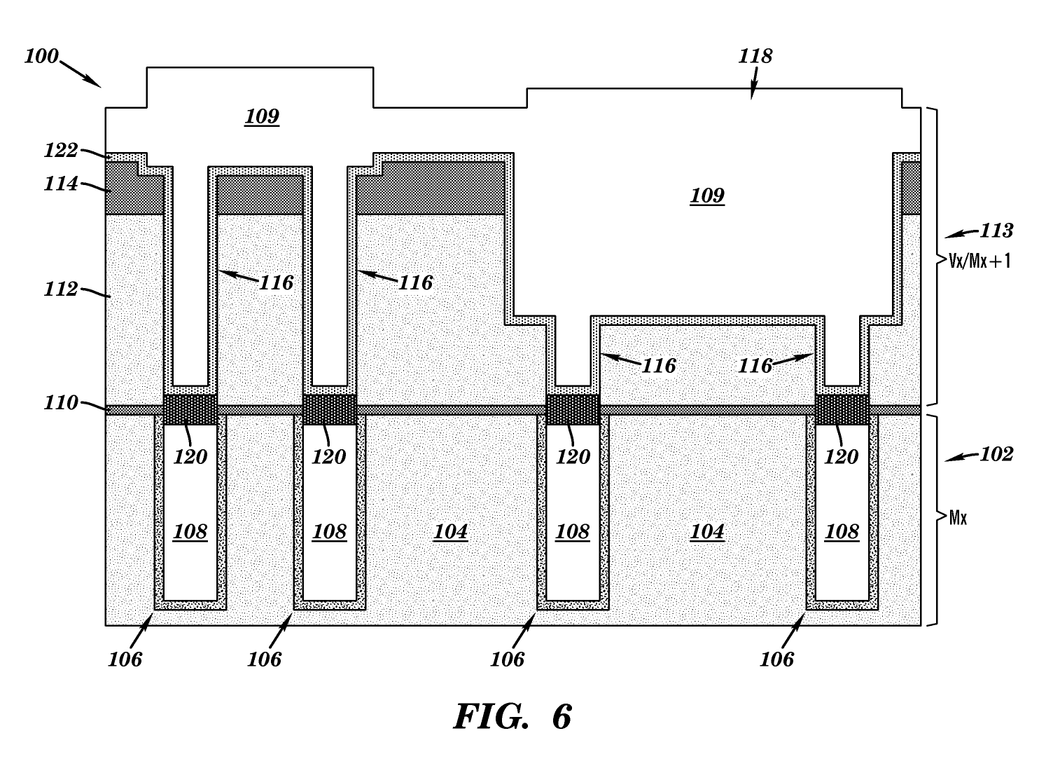

Referring now to FIG. 6, a second conductive material 109 may be conformally deposited on a top surface of the barrier liner 122. The second conductive material 109 may be formed by electroplating, electroless plating, PVD, CVD, or any combination thereof. In an embodiment of the present disclosure, the second conductive material 109 may be formed by PVD of a thin seed layer containing a metal (not shown) and electroplating of the same metal. The second conductive material 109 may include copper, however other metals such as aluminum (Al), gold (Au), silver (Ag) and tungsten (W) may also be considered. The second conductive material 109 may further include a dopant, such as, for example, manganese, magnesium, copper, aluminum, or other known dopants.

The thickness of the second conductive material 109 may be enough to entirely fill the vias 116 and the trenches 118. In an embodiment of the present disclosure, the thickness of the second conductive material 109 may exceed the depth of the trenches 118 as shown in the figure. In this case, the thickness of the second conductive material 109 may vary between about 100 nm to about 1 μm.

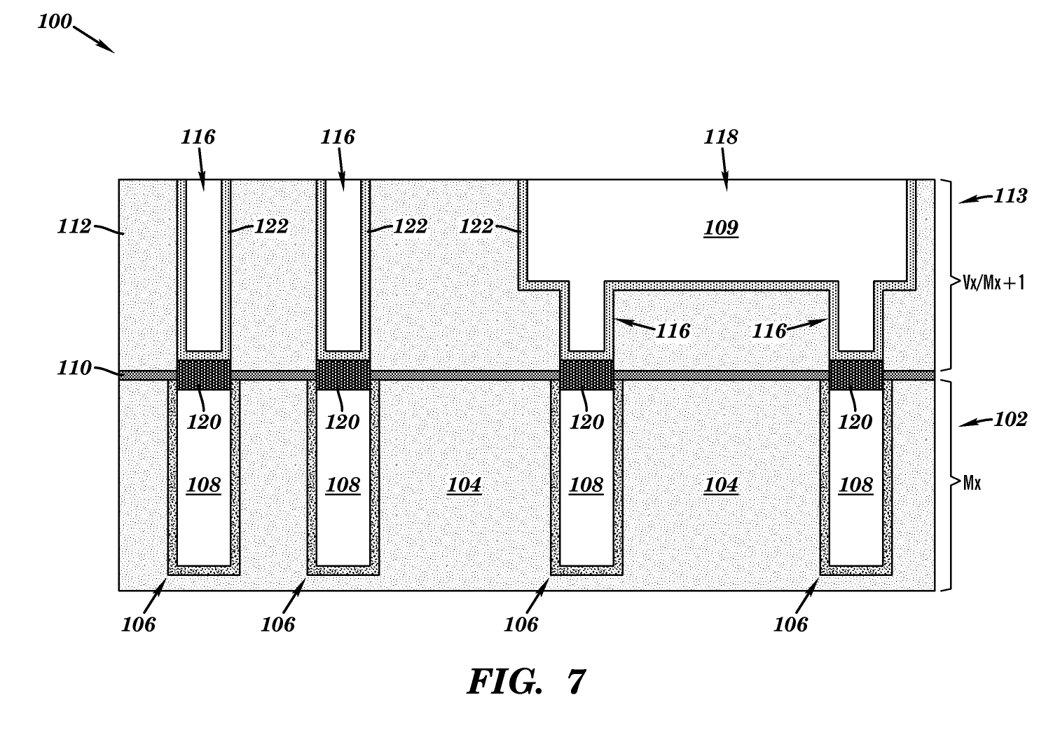

Referring now to FIG. 7, planarization of the second conductive material 109 exceeding the depth of the trenches 118 is shown. The planarization may be conducted by any method known in the art, for example, by chemical mechanical polishing (CMP) of areas of the second conductive material 109 exceeding the depth of the trenches 118. The hardmask layer 114 and uppermost areas of the barrier liner 122 may also be removed during the planarization process.

The barrier layer 122 may also serve as a stop layer during planarization of the excess second conductive material 109. The planarization process then may be a two step-process. The first step may include a self-stopping process to remove the excess second conductive material 109 above the portion of the barrier liner 122 located on top of the uppermost surface of the second ILD layer 112. The second step in the planarization process may include removing the barrier liner 122 from the uppermost surface of the second ILD layer 112 to expose a top of the second ILD layer 112. The planarization process may stop once a desired thickness of the second ILD layer 112 may be reached according to a predetermined chip design. The remaining section of the second conductive material 109 filling the vias 116 and trenches 118 patterned in the second ILD layer 112 may form the structure second metal level 113.

Selectively forming the passivation cap 120 at the bottom of the vias 116 prior to the deposition of the barrier liner 122 may strengthen the interface between the via and the conductive material 108 underneath to prevent early via voiding.

The method aforementioned described may provide a localized copper surface treatment that may not affect the structure resistance-capacitance (RC) performance or time-dependent dielectric-breakdown (TDDB) reliability requirements. Therefore, the formation of a selectively placed passivation cap may offer an alternative to levels in which the use of copper-manganese or cobalt-tungsten-phosphide alloys may not be considered due to time-dependent dielectric-breakdown and/or resistance-capacitance concerns. The formation of a passivation cap may also help levels that currently may use copper-manganese but the manganese segregation to a top surface of the level may not be sufficient to prevent voids between the top surface of the level and a via located in the next level on top.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method of forming an integrated circuit structure, comprising:
forming a cap layer above a first ILD layer of a first metal level, wherein the first ILD layer includes a recess filled with a first conductive material to form a first interconnect structure;
forming a second ILD layer above the cap layer;
forming a via within the second ILD layer as a second interconnect structure of a second metal level, the via being aligned with the first interconnect structure;
removing a portion of the cap layer to extend the via to expose a top portion of the first conductive material; and
selectively forming a passivation cap at a bottom portion of the via in the second ILD layer and the passivation cap contacting the top portion of the first conductive material, wherein the passivation cap includes a metal alloy to form an interface between the bottom portion of the via and the first conductive material.

2. The method of claim 1, wherein selectively forming the passivation cap comprises depositing a substantial amount of the metal alloy in the bottom portion of the via compared with an amount deposited on a sidewall of the via.

3. The method of claim 1, wherein selectively forming the passivation cap comprises positioning the metal alloy substantially within the bottom portion of the via and the top portion of the first conductive material.

4. The method of claim 1, wherein selectively forming the passivation cap at a bottom portion of the via comprises depositing a copper-manganese (CuMn) alloy or a cobalt-tungsten phosphide (CoWP) alloy in the bottom of the via.

5. The method of claim 1, wherein selectively forming the passivation cap comprises depositing the copper-manganese (CuMn) alloy in the bottom of the via using a selective chemical vapor deposition technique.

6. The method of claim 1, wherein selectively forming the passivation cap comprises depositing the cobalt-tungsten phosphide (CoWP) alloy in the bottom of the via using an electroless plating technique.

7. A method of forming an integrated circuit structure, comprising:
forming a cap layer above a first ILD layer of a first metal level, wherein the first ILD layer includes a recess filled with a first conductive material to form a first interconnect structure;
forming a second ILD layer above the cap layer;
forming a dual damascene opening having a via and a trench within the second ILD layer, the via being aligned with the first interconnect structure;
removing a portion of the cap layer to extend the via to expose a top portion of the first conductive material;
selectively forming a passivation cap at a bottom portion of the via in the second ILD layer and the passivation cap contacting the top portion of the first conductive material, wherein the passivation cap includes a metal alloy to form an interface between the bottom portion of the via and the first conductive material;
forming a barrier liner on a perimeter formed by an exposed surface of the via, an exposed surface of the trench, an uppermost part of the second ILD layer and an exposed surface of the passivation cap; and
filling the via and the trench with a second conductive material.

8. The method of claim 7, wherein selectively forming the passivation cap comprises depositing a substantial amount of the metal alloy in the bottom portion of the via compared with an amount deposited on a sidewall of the via.

9. The method of claim 7, wherein selectively forming the passivation cap comprises positioning the metal alloy substantially within the bottom portion of the via and the top portion of the first conductive material.

10. The method of claim 1, wherein selectively forming the passivation cap at a bottom portion of the via comprises depositing a copper-manganese (CuMn) alloy or a cobalt-tungsten phosphide (CoWP) alloy in the bottom of the via.

11. The method of claim 7, wherein selectively forming the passivation cap comprises depositing the copper-manganese (CuMn) alloy in the bottom of the via using a selective chemical vapor deposition technique.

12. The method of claim 7, wherein selectively forming the passivation cap comprises depositing the cobalt-tungsten phosphide (CoWP) alloy in the bottom of the via using an electroless plating technique.

13. The method of claim 7, wherein forming the cap layer above the first ILD layer comprises depositing a nitrogen-doped silicon carbide material (NBLoK) above the first ILD layer.

14. The method of claim 7, wherein removing the portion of the cap layer comprises continuing an anisotropic etching technique used to form the via until exposing a top portion of the first conductive material.

15. The method of claim 7, wherein forming the barrier liner comprises depositing (Ti), tantalum (Ta), tungsten (W), titanium nitride (TiN), tantalum nitride (TaN), tungsten nitride (WN), a combination of (Ti), tantalum (Ta), tungsten (W), titanium nitride (TiN), tantalum nitride (TaN), tungsten nitride (WN) or an alloy thereof.

16. The method of claim 7, wherein filling the via and the trench with a second conductive material comprises depositing copper (Cu) or a copper alloy within the via and the trench.

17. An integrated circuit structure comprising:
a first ILD layer having a recess filled with a first conductive material being part of a first interconnect structure of a first metal level;
a second ILD layer having a recess filled with a second conductive material being part of a second interconnect structure of a second metal level, wherein the second interconnect structure includes a via extending to a top portion of the first conductive material;
a cap layer positioned between the first ILD layer and the second ILD layer located essentially in an area between two vias; and
a passivation cap positioned at a bottom portion of the via and at an exposed top portion of the first conductive material, wherein the passivation cap forms an interface between the via bottom and the first conductive material.

18. The integrated circuit structure of claim 18, wherein the passivation cap comprises a copper-manganese (CuMn) alloy or a cobalt-tungsten phosphide (CoWP) alloy.

19. The integrated circuit structure of claim 18, further comprising:
a barrier liner located above a top surface of a perimeter formed by an exposed surface of the second interconnect structure, an uppermost part of the second ILD layer and an exposed surface of the passivation cap;
a second conductive material positioned on top of the barrier liner filling the second interconnect structure.

20. The integrated circuit structure of claim 19, wherein the second conductive material comprises copper or a copper alloy.
